(19) United States
(12) Patent Application Publication
(10) Pub. No.: US 2024/0266148 A1
(43) Pub. Date: Aug. 8, 2024

(54) SEMICONDUCTOR MANUFACTURING DEVICE

(71) Applicant: SAMSUNG ELECTRONICS CO., LTD., SUWON-SI (KR)

(72) Inventors: Min Su LEE, Suwon-si (KR); Yeon Tae KIM, Suwon-si (KR); Yon Joo KANG, Suwon-si (KR); Yi Hwan KIM, Suwon-si (KR); Won Ki LEE, Suwon-si (KR); Hyeon Jin JEON, Suwon-si (KR); Hyeong Un JEON, Suwon-si (KR)

(21) Appl. No.: 18/416,990

(22) Filed: Jan. 19, 2024

(30) Foreign Application Priority Data
Feb. 6, 2023 (KR) 10-2023-0015423

(51) Int. Cl. H01J 37/32; C23C 16/455; C23C 16/50

(52) U.S. Cl. CPC H01J 37/3244; C23C 16/45565; C23C 16/50; H01J 37/32724; H01J 2237/3343

(57) ABSTRACT

A semiconductor manufacturing device comprising a support unit in a chamber. A showerhead disposed between first and second plasma regions. First and second gas supply units injecting first and second process gases, respectively, into the second plasma region through the showerhead. The showerhead includes plasma penetration portions passing a portion of the plasma generated in the first plasma region therethrough. First gas flow paths injecting the first process gas into a first zone of the showerhead. Second gas flow paths injecting the second process gas into a second zone of the showerhead that surrounds the first zone. First and second cavities connected to the first and second gas flow paths, respectively. The first and second cavities diffusing the first and second process gases, respectively. First and second gas spraying holes connected to the first and second cavities, respectively, and facing the second plasma region.

### CROSS-REFERENCE TO RELATED APPLICATION

This application claims priority under 35 U.S.C. § 119 to Korean Patent Application No. 10-2023-0015423, filed on Feb. 6, 2023 in the Korean Intellectual Property Office, the disclosure of which is incorporated by reference in its entirety herein.

### 1. TECHNICAL FIELD

The present disclosure relates to a semiconductor manufacturing device.

### 2. DISCUSSION OF RELATED ART

Plasma is widely used in processes for fabricating a semiconductor device, a plasma display panel (PDP), a liquid crystal display (LCD), a solar cell, and the like. Examples of processes using plasma include dry etching, dry cleaning, plasma enhanced chemical vapor deposition (PECVD), sputtering, and ashing. Generally, capacitively coupled plasma (CCP), inductively coupled plasma (ICP), a mixture of CCP and ICP, helicon plasma, microwave plasma, and the like are used in such processes using plasma. To increase product reliability during the processing of a substrate with the use of plasma, damage that may be caused to the substrate by high-energy plasma needs to be minimized. Therefore, research is being conducted to reduce plasma damage on a substrate.

### SUMMARY

Aspects of embodiments of the present disclosure provide a semiconductor manufacturing device for increasing reaction distribution when processing a substrate with plasma.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of embodiments of the present disclosure given below.

According to an embodiment of the present disclosure, a semicondctor manufacturing device includes a chamber including a space for performing processes therein. A support unit is in the chamber. The support unit supports a substrate. A first plasma region is in the chamber. Plasma based on a source gas is generated in the first plasma region. A second plasma region is in the chamber and positioned below the first plasma region. The support unit is disposed in the second plasma region. A showerhead is disposed between the first plasma region and the second plasma region. A first gas supply unit injects a first process gas into the second plasma region through the showerhead. A second gas supply unit injects a second process gas into the second plasma region through the showerhead. The showerhead includes plasma penetration portions passing a portion of the plasma generated in the first plasma region therethrough. First gas flow paths inject the first process gas into a first zone of the showerhead. The first gas flow paths are connected to the first gas supply unit. Second gas flow paths inject the second process gas into a second zone of the showerhead that surrounds the first zone. The second gas flow paths are connected to the second gas supply unit. A first cavity is connected to the first gas flow paths. The first process gas diffuses into the first cavity. A second cavity is connected to the second gas flow paths. The second process gas diffuses into the second cavity. First gas spraying holes are connected to the first cavity and face the second plasma region. Second gas spraying holes are connected to the second cavity and face the second plasma region.

According to an embodiment of the present disclosure, a semicondctor manufacturing device includes a first plate including first plasma openings penetrating the first plate, first gas flow paths injecting a first process gas into a first zone, and second gas flow paths inject a second process gas into a second zone that surrounds the first zone. A second plate includes second plasma openings penetrating the second plate and are connected to the first plasma openings, first holes passing the first process gas therethrough, second holes passing the second process gas therethrough, a first cavity diffusing the first process gas injected through the first holes, and a second cavity diffusing the second process gas injected through the second holes. A third plate includes third plasma openings connected to the first plasma openings and the second plasma openings, first gas spraying holes passing the first process gas from the first cavity therethrough and spraying the first process gas to an outside of the showerhead, and second gas spraying holes passing the second process gas from the second cavity therethrough and spraying the second process gas to the outside of the showerhead. The first and second plates are bonded together. A bottom surface of the first plate and an upper surface of the second plate face each other. The second and third plates are bonded together. A bottom surface of the second plate and an upper surface of the third plate face each other.

According to an embodiment of the present disclosure, a semicondctor manufacturing device includes a first plate including first plasma openings penetrating the first plate. A second plate includes second plasma openings penetrating the second plate, the second plasma openings are connected to the first plasma openings. The second plate further includes first gas flow paths injecting a first process gas into a first zone, second gas flow paths injecting a second process gas into a second zone that surrounds the first zone, a first cavity disposed in the first zone. The first process gas is injected into the first cavity through the first gas flow paths. A second cavity is disposed in the second zone. The second process gas is injected into the second cavity through the second gas flow paths. First gas spraying holes spray the first process gas from the first cavity to an outside of the showerhead. Second gas spraying holes spray the second process gas from the second cavity to the outside of the showerhead. The showerhead includes the first and second plates bonded together. A bottom surface of the first plate and an upper surface of the second plate face each other.

It should be noted that effects of embodiments of the present disclosure are not necessarily limited to those described above, and other effects of embodiments of the present disclosure will be apparent from the following description.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a diagram of a plasma processing apparatus according to an embodiment of the present disclosure.

FIG. 2 is a plan view of a showerhead according to an embodiment of the present disclosure.

FIG. 3 is an exploded perspective view of a showerhead according to an embodiment of the present disclosure.

FIG. 4 is an exploded perspective view of the showerhead of FIG. 3, as viewed from therebelow.

FIG. 5 is a diagram illustrating the upper surface of a first plate shown in FIG. 3 according to an embodiment of the present disclosure.

FIG. 6 is a diagram illustrating the bottom surface of the first plate shown in FIG. 3 according to an embodiment of the present disclosure.

FIGS. 7 and 8 are diagrams illustrating first gas flow paths and second gas flow paths shown in FIG. 6 according to embodiments of the present disclosure.

FIG. 9 is a diagram illustrating the upper surface of a second plate shown in FIG. 3 according to an embodiment of the present disclosure.

FIG. 10 is a diagram illustrating the bottom surface of the second plate shown in FIG. 3 according to an embodiment of the present disclosure.

FIG. 11 is a diagram of a third plate shown in FIG. 3 according to an embodiment of the present disclosure.

FIG. 12 is a cross-sectional view, taken along line I-I, of the showerhead of FIG. 3 according to an embodiment of the present disclosure.

FIG. 13 is an exploded perspective view of a showerhead according to an embodiment of the present disclosure.

FIG. 14 is a diagram of a first plate shown in FIG. 13 according to an embodiment of the present disclosure.

FIG. 15 is a diagram of a second plate shown in FIG. 13 according to an embodiment of the present disclosure.

FIG. 16 is a cross-sectional view, taken along line II-II, of the showerhead of FIG. 13 according to an embodiment of the present disclosure.

### DETAILED DESCRIPTION OF EMBODIMENTS

A semicondctor manufacturing device including the same according to some embodiments of the present disclosure will hereinafter be described with the accompanying drawings.

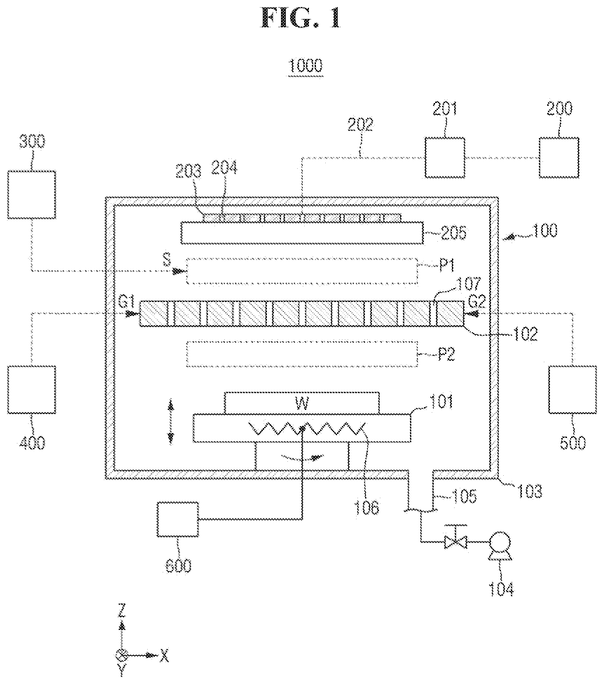

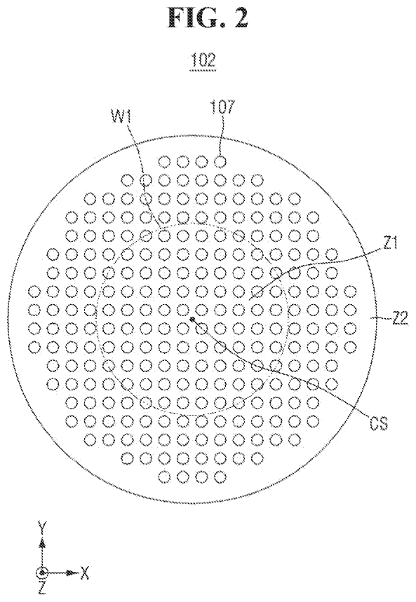

FIG. 1 is a diagram of a plasma processing apparatus according to some embodiments of the present disclosure. FIG. 2 is a plan view of a showerhead according to some embodiments of the present disclosure.

Referring to FIG. 1, in an embodiment a plasma processing apparatus 1000 may include a chamber 100, a support unit 101, a plasma source 200, a first plasma region P1, a second plasma region P2, a showerhead 102, a first gas supply unit 300, a second gas supply unit 400, and a third gas supply unit 500.

The chamber 100 may provide space in which a semiconductor device may be fabricated by processing a substrate W with plasma. For example, in an embodiment deposition, etching, annealing, and rinsing processes may be performed on the substrate W in the chamber 100. However, embodiments of the present disclosure are not necessarily limited thereto. The name of the plasma processing apparatus 1000 may vary depending on the function of the chamber 100. For example, the plasma processing apparatus 1000 may also be referred to as a deposition apparatus, an etching apparatus, an annealing apparatus, or a rinsing apparatus depending on the type of process performed in the chamber 100, such as, for example, a deposition, etching, annealing, or rinsing process. In an embodiment, some of the deposition, etching, annealing, and rinsing processes may be performed together in the chamber 100. For example, the etching and rising processes may be performed together in the chamber 100.

Here, the substrate W may refer to the substrate W alone or a stack of the substrate W and at least one predetermined layer or film formed on the surface of the substrate W. The surface of the substrate W may refer to the surface of the substrate W or the surface of the predetermined layer or film formed on the substrate of the substrate W. For example, in an embodiment the substrate W may be a wafer or a wafer with at least one material film formed on the substrate W. In an embodiment, the material film may be an insulating film and/or a conductive film formed on the wafer by various methods such as deposition, coating, or plating. For example, the insulating film may include an oxide film, a nitride film, or an oxynitride film, and the conductive film may include a metal film or a polysilicon film. The material film may be formed on the wafer to have a predetermined pattern.

The chamber 100 may have an enclosed space having a predetermined size. The chamber 100 may be formed in various arrangements in accordance with the shape and size of the substrate W. For example, in an embodiment the chamber 100 may have a cylindrical shape corresponding to a disk-shaped substrate W. However, the shape of the chamber 100 is not necessarily limited thereto. The chamber 100 may include a conductive member such as an aluminum (Al) member. The conductive member may be maintained to be electrically grounded to block external noise during a plasma process.

In an embodiment, a liner 103 may be disposed on the inside of the chamber 100. The liner 103 may protect the chamber 100 and may cover metal structures in the chamber 100 to prevent metal contamination that may be caused by arcing inside the chamber 100. In an embodiment, the liner 103 may be formed of a metal material such as Al or a ceramic material. In an embodiment, the liner 103 may also be formed of a material film resistant to plasma, on the side of the first plasma region P1. The material film resistant to plasma may be, for example, an yttrium oxide (Y₂O₃) film. However, embodiments of the present disclosure are not necessarily limited thereto.

An outlet 105 may be formed at a lower part of the chamber 100. The outlet 105 may be connected to a vacuum pump 104, such as a dry pump. Materials generated in the chamber 100 during a plasma process, such as polymers, may be discharged to the outside through the outlet 105. The vacuum pump 104 may control the pressure in the chamber 100.

The support unit 101 is disposed inside the chamber 100 and supports the substrate W. In an embodiment, the support unit 101 may be connected to a motor and may thus rotate the substrate W, which is placed on the upper surface of the support unit 101. For example, in an embodiment the support unit 101 may rotate the substrate W at about 1 rotations per minute (RPM) or higher. However, embodiments of the present disclosure are not necessarily limited thereto. Accordingly, when fabricating a semiconductor device by processing the substrate W in the chamber 100, the surface of the substrate W can be uniformly processed without overly focused on certain parts of the surface of the substrate W. For example, the uniformity of deposition on the surface of the substrate W can be increased during a deposition process, and the uniformity of etching on the surface of the substrate W may be increased during an etching process.

In an embodiment, the support unit 101 may move in a first direction Z and in the opposite direction of the first direction Z, and as a result, the substrate W, which is placed on the support unit 101, may also move in the first direction Z and in the opposite direction of the first direction Z. Accordingly, when the surface of the substrate W is processed by generating plasma in the chamber 100, the energy level of plasma reaching the surface of the substrate W can be controlled by adjusting the distance of the plasma to the substrate W. Therefore, the degree of deposition or etching on the surface of the substrate W can be controlled.

In an embodiment, the support unit 101 may include a heater 106 which heats the substrate W to control the temperature of the substrate W. In an embodiment, the heater 106 is embedded in the support unit 101 and may heat the substrate W by heating the support unit 101 with power from a heater power source 600. In an embodiment, the support unit 101 may be an electrostatic chuck supporting the substrate W with an electrostatic force. However, embodiments of the present disclosure are not necessarily limited thereto. In an embodiment in which the support unit 101 is implemented as an electrostatic chuck, the support unit 101 may include a dielectric plate, on which the substrate W is placed, and an electrode, which is installed in the dielectric plate and provides an electrostatic force so that the substrate W is adsorbed onto (e.g., secured thereon) the dielectric plate.

The plasma source 200 may be any suitable source capable of generating plasma in the chamber 100. For example, in an embodiment the plasma source 200 may be radio frequency (RF) capacitively coupled plasma (CCP), RF inductively coupled plasma (ICP), or microwave plasma in the form of electromagnetic waves having a predetermined frequency and intensity. The plasma source 200 will hereinafter be described as being, for example, a microwave plasma source for convenience of description and not necessarily limitation. Microwaves generated from the plasma source 200 may propagate to an antenna 203 via a matching circuit 201 and a waveguide 202. The microwaves supplied to the antenna 203 are radiated from microwave radiation holes 204 of the antenna 203 through a microwave transmission plate 205 to the space on the substrate W, in the chamber 100. An electromagnetic field may be generated in the chamber 100 by the microwaves. However, in an embodiment in which the plasma source 200 is an RF CCP source or an RF ICP source, an electromagnetic field may be generated in the chamber 100 by applying high-frequency power to the electrode of the support unit 101 or electrode disposed on the upper part of the inside of the chamber 100 via a high-frequency power supply unit.

The first gas supply unit 300 may inject a source gas S for generating plasma into the first plasma region P1 in the chamber 100. For example, in an embodiment the source gas S may include Ar, N₂, He, or H₂. However, embodiments of the present disclosure are not necessarily limited thereto. FIG. 1 illustrates that only the first gas supply unit 300 injects the source gas into the first plasma region P1. However, embodiments of the present disclosure are not necessarily limited thereto. For example, in an embodiment two or more independent gas supply units may be provided to inject two or more source gases into the first plasma region P1.

In the first plasma region P1, plasma may be generated based on the source gas supplied by the first gas supply unit 300. The electromagnetic field generated in the chamber 100 by the plasma source 200 may excite the source gas S into a plasma state to generate plasma. In an embodiment, the plasma generated in the first plasma region P1 may include various ingredients such as radicals, ions, electrons, ultraviolet (UV) light, and the like. At least one of the ingredients of the plasma generated in the first plasma region P1 may be used to process the substrate W such as, for example, in a deposition, etching or rinsing process. Radicals that are electrically neutral may be used to interfere with or suppress the deposition of particular ingredients during a deposition process using plasma. Radicals may also be used to remove targets to be etched away during an etching process using plasma and to isotropically remove targets to be rinsed off during a rinsing process using plasma. Ions that are electrically polar may be used to anisotropically remove targets to be etched away during an etching process using plasma and to anisotropically remove targets to be rinsed off during a rinsing process using plasma.

The second plasma region P2 may be disposed below the first plasma region P1, and the support unit 101 may be disposed in the second plasma region P2. The second plasma region P2 may include a process region in which the substrate W is to be processed. In the second plasma region P2, low-temperature plasma passing through the showerhead 102, among the plasma included in the first plasma region P1 may react with first and second process gases G1 and G2, which are supplied into the second plasma region P2 through the showerhead 102, and as a result, an etchant may be generated for removing targets to be etched away or rinsed off or a deposition material.

Referring to FIGS. 1 and 2, the showerhead 102 may be disposed between the first and second plasma regions P1 and P2 (e.g., in the Z direction). The showerhead 102 may be positioned between the first and second plasma regions P1 and P2 and may thus separate and divide the first and second plasma regions P1 and P2 from each other. In an embodiment, the showerhead 102 may include quartz and may have, for example, a plate shape (e.g., a disk shape), as illustrated in FIG. 2. The showerhead 102 may include a plurality of plasma penetration portions 107, which extend in the first direction Z.

In an embodiment, the showerhead 102 may transmit only plasma having an electronic temperature that is less than or equal to a preset electronic temperature, among the plasma included in the first plasma region P1, through the plasma penetration portions 107 to the second plasma region P2. For example, during a deposition process using plasma, the showerhead 102 may transmit only a portion of the plasma having the preset electronic temperature or lower, among the plasma included in the first plasma region P1, through the plasma penetration portions 107 to prevent defects from being generated on the surface of the substrate W due to a vapor reaction caused by high-temperature plasma energy.

In an embodiment, during an etching or rinsing process using plasma, radicals that are electrically neutral, may be supplied into the second plasma region P2 through the plasma penetration portions 107 of the showerhead 102. However, ions may not be able to pass through the plasma penetration portions 107. The showerhead 102 may function to substantially reduce or remove ions moving from the first plasma region P1 to the second plasma region P2. For example, the showerhead 102 may be used to filter out plasma ingredients moving from the first plasma region P1 to the second plasma region P2.

In an embodiment, the filtering function of the showerhead 102 may be achieved by the geographical shape of the plasma penetration portions 107, such as by the aspect ratio or tapered shape of the plasma penetration portions 107. For example, as the length in a second direction X of the plasma penetration portions 107 decreases and the length in the first direction Z of the plasma penetration portions 107 increases, only plasma having low energy can pass through the plasma penetration portions 107 to reach the second plasma region P2. The second direction X may cross the first direction Z. For example, in an embodiment, the second direction X may be orthogonal to the first direction Z.

In an embodiment, by controlling the aspect ratio of the plasma penetration portions 107, the electronic temperature of the plasma included in the first plasma region P1 may be made to be in a range of about 1.5 times or greater the electronic temperature of plasma included in the second plasma region P2. Also, in an embodiment by controlling the aspect ratio of the plasma penetration portions 107, the electronic temperature of the plasma included in the first plasma region P1 may be made to be in a range of about 0.5 eV or greater and the electronic temperature of the plasma included in the second plasma region P2 may be made to be in a range of about less than 0.5 eV.

The showerhead 102 can filter out plasma having the preset electronic temperature or higher from among the plasma included in the first plasma region P1 or can filter out some ingredients of the plasma included in the first plasma region P1. Also, the showerhead 102 can function as a path for injecting the first and second process gases G1 and G2 into the chamber 100 or can uniformly eject the first and second process gases G1 and G2 into the second plasma region P2. The shape and the functions of the showerhead 102 will be described later.

In an embodiment, the second gas supply unit 400 may inject the first process gas G1 into a first zone Z1 (FIG. 2) of the showerhead 102. The third gas supply unit 500 may inject the second process gas G2 into a second zone Z2 (FIG. 2) of the showerhead 102. As illustrated in FIG. 2, in an embodiment the first zone Z1 of the showerhead 102, which is disk-shaped, may be a center area, and the second zone Z2 of the showerhead 102 may be an edge area surrounding the first zone Z1. As will be described later, the first and second zones Z1 and Z2 may be separated and divided by a partition W1. The first zone Z1 of the showerhead 102 may correspond to a center area of the surface of the substrate W, and the second zone Z2 of the showerhead 102 may correspond to an edge area of the surface of the substrate W surrounding the center area.

FIG. 1 illustrates that two gas supply units, such as the second and third gas supply units 400 and 500, are connected to sides of the showerhead 102. However, the number of gas supply units connected to the showerhead 102 is not necessarily limited thereto. Alternatively, three or more gas supply units for injecting process gases into the showerhead 102 may be provided. Also, the number of zones of the showerhead 102 may vary depending on the number of gas supply units connected to the showerhead 102. For example, in an embodiment in which three gas supply units are connected to the showerhead 102, the showerhead 102 may be divided into three zones that are concentric with respect to a center CS (FIG. 2) of the showerhead 102, which is disk-shaped. By controlling the number of gas supply units connected to the showerhead 102, different areas on the surface of the substrate W that correspond to different zones of the showerhead 102 can be processed independently.

The type of the first and second process gases G1 and G2 may vary depending on the type of plasma process performed in the chamber 100. For example, in an embodiment in which a deposition process is performed in the chamber 100, the first and second process gases G1 and G2 may be deposition gases such as SiH₄ or DCS. For example, when an etching process is performed in the chamber 100, the first and second process gases G1 and G2 may be etching gases such as H₂, HCl, or Cl₂. Alternatively, the first and second process gases G1 and G2 may be doping gases such as PH₃, B₂H₆, or GeH₄. In an embodiment, a source gas S for generating plasma, such as Ar, N₂, or He, may be injected into the showerhead 102 via the second and third gas supply units 400 and 500 and may be used later as a carrier for controlling the distribution on the surface of the substrate W when processing the substrate W.

The type of the first and second process gases G1 and G2 may also vary depending on the types of a target material and the source gas S. For example, in an embodiment in which an etching process is performed in the chamber 100, the target material is silicon oxide (SiO₂), and the source gas S is nitrogen trifluoride (NF₃), the first and second process gases G1 and G2 may be ammonia (NH₃) gases and may further include auxiliary gases such as, for example, a nitrogen gas (N₂) or an inert gas (e.g., He). The first and second process gases G1 and G2 may be the same gases or different gases from each other. In an embodiment, the first and second process gases G1 and G2 may be provided into the chamber 100 in their non-excited (e.g., a non-plasma) state.

The amount of the first process gas G1 supplied to the first zone Z1 of the showerhead 102 via the second gas supply unit 400 and the amount of the second process gas G2 supplied to the second zone Z2 of the showerhead 102 via the third gas supply unit 500 may be controlled. For example, to uniformly deposit a thin film on the surface of the substrate W during a deposition process, the amount of the second process gas G2 supplied to the second zone Z2 of the showerhead 102, which corresponds to the edge area of the substrate W, may be controlled to be greater than the amount of the first process gas G1 supplied to the first zone Z1 of the showerhead 102, which corresponds to the center area of the substrate W. For example, to uniformly etch the surface of the substrate W during an etching process, the amount of the second process gas G2 supplied to the second zone Z2 of the showerhead 102, which corresponds to the edge area of the substrate W, may be controlled to be greater than the amount of the first process gas G1 supplied to the first zone Z1 of the showerhead 102, which corresponds to the center area of the substrate W.

Also, the amount of the source gas S injected into the first plasma region P1 in the chamber 100 via the first gas supply unit 300 and the amounts of the first and second process gases G1 and G2 injected into the second plasma region P2 in the chamber 100 via the second and third gas supply units 400 and 500 may be separately controlled in accordance with the type of plasma process performed in the chamber 100. For example, in an embodiment in which an etching process is performed requiring high-energy plasma, the amount of the source gas S injected into the first plasma region P1 in the chamber 100 via the first gas supply unit 300 may be controlled to be greater than the amounts of the first and second process gases G1 and G2 injected into the showerhead 102 via the second and third gas supply units 400 and 500. For example, in an embodiment in which a deposition process that may cause defects on the surface of the substrate W due to a vapor reaction caused by high-temperature plasma is performed, the amounts of the first and second process gases G1 and G2 injected into the showerhead 102 and the second plasma region P2 via the second and third gas supply units 400 and 500 may be controlled to be greater than the amount of the source gas S injected into the first plasma region P1 in the chamber 100 via the first gas supply unit 300.

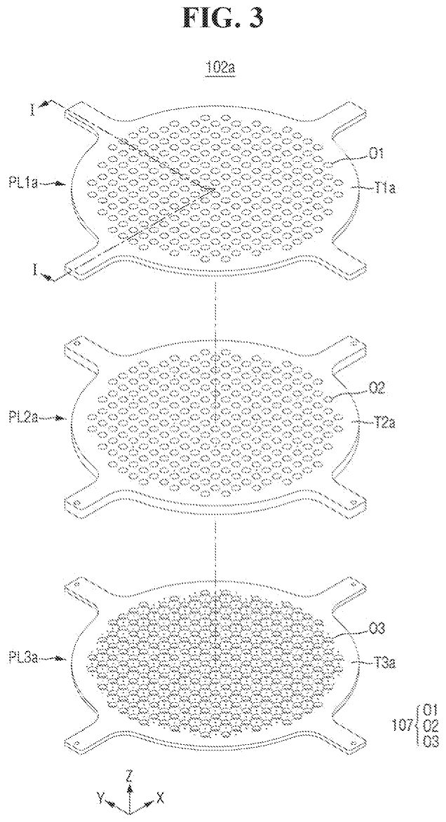

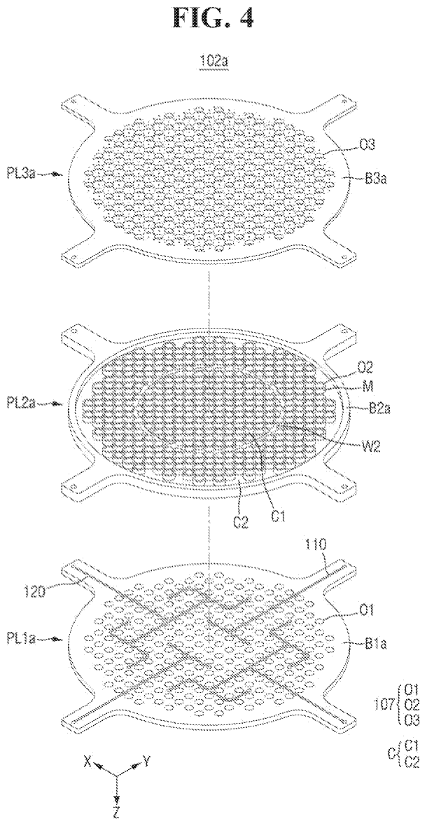

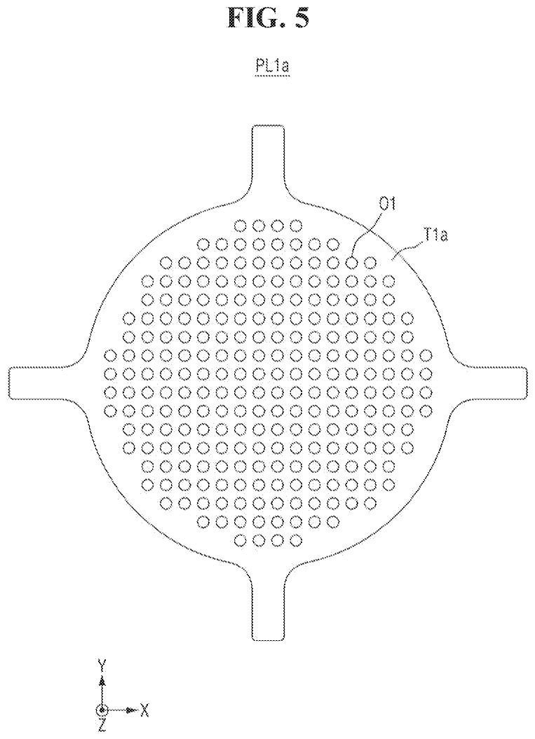

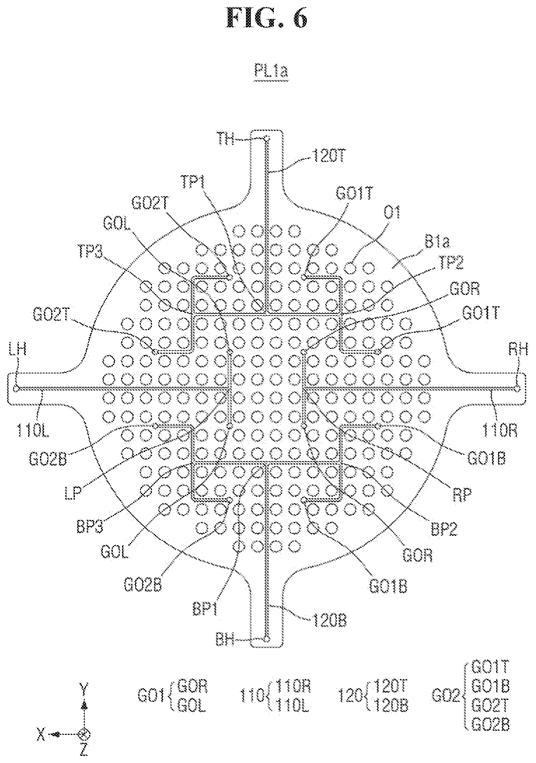

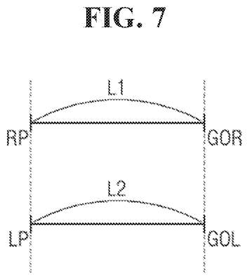

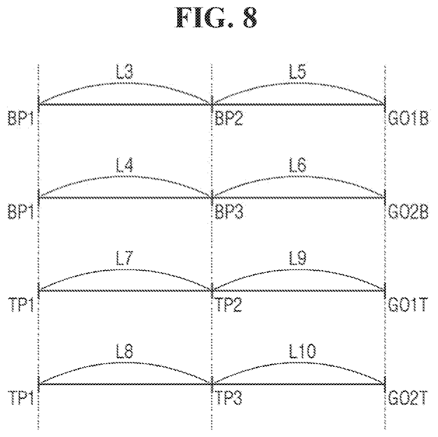

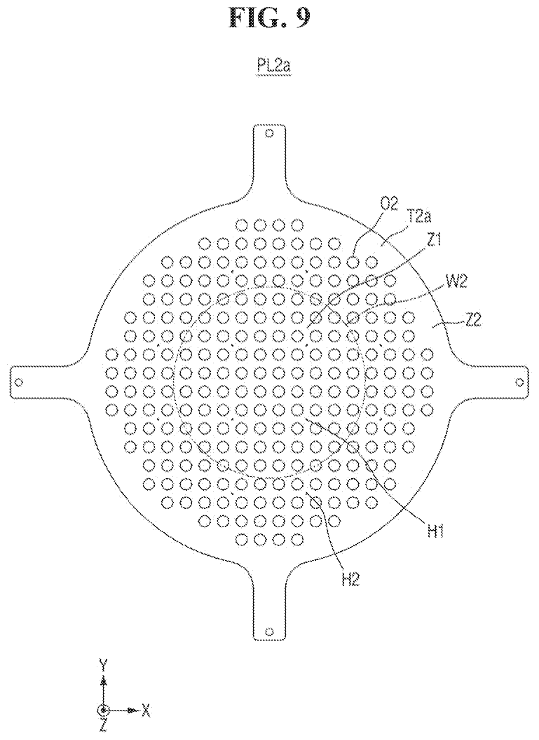

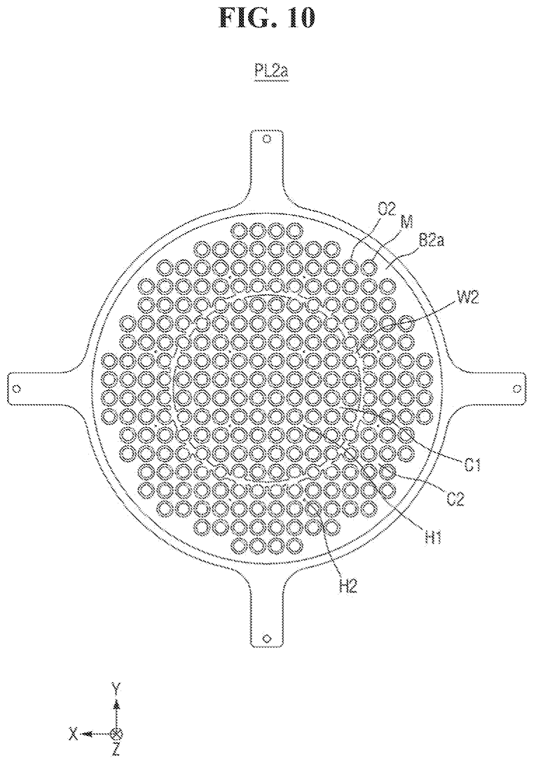

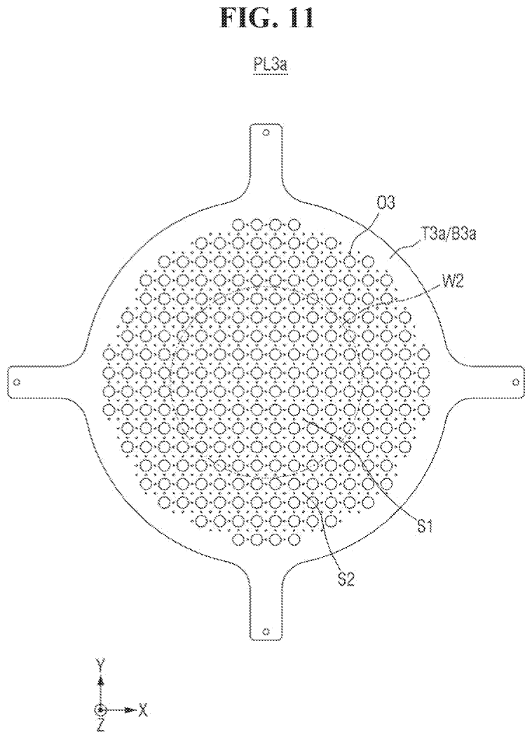

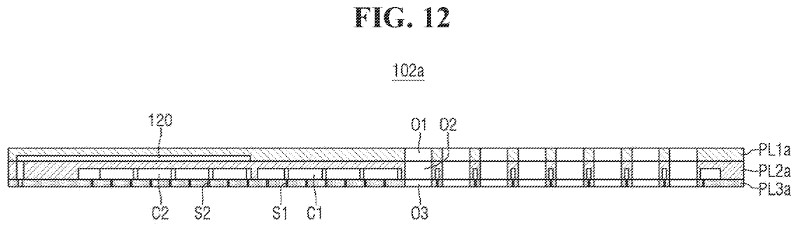

FIG. 3 is an exploded perspective view of a showerhead according to some embodiments of the present disclosure. FIG. 4 is an exploded perspective view of the showerhead of FIG. 3, as viewed from therebelow. FIG. 5 is a diagram illustrating the upper surface of a first plate shown in FIG. 3. FIG. 6 is a diagram illustrating the bottom surface of the first plate shown in FIG. 3. FIGS. 7 and 8 are diagrams illustrating first gas flow paths and second gas flow paths shown in FIG. 6. FIG. 9 is a diagram illustrating the upper surface of a second plate of FIG. 3. FIG. 10 is a diagram illustrating the bottom surface of the second plate shown in FIG. 3. FIG. 11 is a diagram of a third plate shown in FIG. 3. FIG. 12 is a cross-sectional view, taken along line I-I, of the showerhead of FIG. 3. The showerhead of FIG. 3 will hereinafter be described with reference to FIGS. 3 through 12.

A showerhead 102a may be formed by bonding first, second, and third plates PL1a, PL2a, and PL3a to each other. For example, in an embodiment the showerhead 102a may be formed by bonding a bottom surface B1a of the first plate PL1a and an upper surface T2a of the second plate PL2a together and bonding a bottom surface B2a of the second plate PL2a and an upper surface T3a of the third plate PL3a.

The first plate PL1a may include first plasma openings O1, which penetrate the first plate PL1a. The second plate PL2a may include second plasma openings O2, which penetrate the second plate PL2a. The third plate PL3 may include third plasma openings O3, which penetrate the third plate PL3a. When the first and second plates PL1a and PL2a are bonded together, the first plasma openings O1 and the second plasma openings O2 may overlap with each other (e.g., in the Z direction), and be connected to one another. Also, when the second and third plates PL2a and PL3a are bonded together, the second plasma openings O2 and the third plasma openings O3 may overlap with each other (e.g., in the Z direction) and be connected to one another. In an embodiment in which the showerhead 102a is formed by bonding the first, second, and third plates PL1a, PL2a, and PL3a together, the first plasma openings O1, the second plasma openings O2, and the third plasma openings O3 may overlap with each other (e.g., in the Z direction), and be connected to one another, thereby forming plasma penetration portions (“107” of FIG. 1) together. Only some of plasma included in the first plasma region P1 of FIG. 1, which is on the upper surface of the first plate PL1a, can be delivered to the second plasma region P2 of FIG. 1, which is disposed on a bottom surface B3a of the third plate PL3a, passing through the showerhead 102a through the plasma penetration portions 107 formed in the showerhead 102a.

First gas flow paths 110 (FIG. 6) and second gas flow paths 120 (FIG. 6) may be formed on the bottom surface B1a of the first plate PL1a. In an embodiment, the first gas flow paths 110 may be connected to the second gas supply unit 400, and as a result, the first process gas G1 may be injected into the showerhead 102a through the first gas flow paths 110. Also, the second gas flow paths 120 may be connected to the third gas supply unit 500, and as a result, the second process gas G2 may be injected into the showerhead 102a. In an embodiment, the first gas flow paths 110 may inject the first process gas G1 into the first zone Z1, which is the center area of the showerhead 102a, and the second gas flow paths 120 may inject the second process gas G2 into the second zone Z2, which is the edge area of the showerhead 102. The first and second process gases G1 and G2 can be injected into the showerhead 102a through separate independent gas flow paths, such as the first gas flow paths 110 and the second gas flow paths 120.

First gas openings GO1 may be formed at the ends of the first gas flow paths 110 so that the first process gas G1 injected into the showerhead 102a (FIG. 3) through the first gas flow paths 110 may move to the second plate PL2a. Similarly, the second process gas G2 injected into the showerhead 102a may move to the second plate PL2a through second gas openings GO2, which are formed at the ends of the second gas flow paths 120.

In an embodiment, cavities C (FIG. 4) may be formed in the second plate PL2a. Cylindrical members M, which are connected to the second plasma openings O2, may be formed at the bottom surface B2a of the second plate PL2a. Due to the width of the cylindrical member M, (e.g., in the second and third directions X, Y) the cavities C may be formed in the second plate PL2a.

The cavities C may be divided into first and second cavities C1 and C2 by a partition W2 (FIG. 10), which is formed at the bottom surface B2a of the second plate PL2a. The first cavity C1 which corresponds to the first zone Z1 of the showerhead 102a may be formed in the center area of the showerhead 102a. The second cavity C2, which corresponds to the second zone Z2 of the showerhead 102a may be formed in the edge area of the showerhead 102a.

First holes H1 (FIG. 9) which are connected to the first gas flow paths 110 and second holes H2 (FIG. 9) which are connected to the second gas flow paths 120 may be formed at the upper surface T2a of the second plate PL2a. When the first and second plates PL1a and PL2a are bonded together, the first gas openings GO1, which are formed at the bottom surface B1a of the first plate PL1a, may overlap with the first holes H1 (e.g., in the Z direction), which are formed at the upper surface T2a of the second plate PL2a. Also, when the first and second plates PL1a and PL2a are bonded together, the second gas openings GO2, which are formed at the bottom surface B1a of the first plate PL1a, may overlap with the second holes H2 (e.g., in the Z direction) which are formed at the upper surface T2a of the second plate PL2a. Accordingly, the first process gas G1 can diffuse into the first cavity C1 through the first holes H1, and the second process gas G2 can diffuse into the second cavity C2 through the second holes H2.

The third plate PL3a may include first gas spraying holes S1 (FIG. 11) and second gas spraying holes S2 (FIG. 11), which are formed towards the second plasma region P2 of FIG. 1. In an embodiment, the first gas spraying holes S1 may be formed in the first zone Z1 of the showerhead 102a, and the second gas spraying holes S2 may be formed in the second zone Z2 of the showerhead 102a. Accordingly, the first process gas G1 diffused into the first cavity C1 through the first holes H1 may be sprayed to the outside of the showerhead 102a into the second plasma region P2 of FIG. 1 through the first gas spraying holes S1, and the second process gas G2 diffused into the second cavity C2 through the second holes H2 may be sprayed to the outside of the showerhead 102a and into the second plasma region P2 through the second gas spraying holes S2.

In some embodiments, the number of first gas spraying holes S1 may be greater than the number of first holes H1. Also, the number of second gas spraying holes S2 may be greater than the number of second holes H2. Accordingly, the first process gas G1 can diffuse over a relatively large area on the surface of the substrate W when sprayed into the second plasma region P2 of FIG. 1 from the first cavity C1 through the first gas spraying holes S1, and the second process gas G2 can also diffuse over a relatively large area on the surface of the substrate W when sprayed into the second plasma region P2 from the second cavity C2 through the second gas spraying holes S2. Therefore, the surface of the substrate W can be uniformly processed.

In an embodiment, the first, second, and third plates PL1a, PL2a, and PL3a may include quartz. Thus, when the showerhead 102a is formed by bonding the first, second, and third plates PL1a, PL2a, and PL3a together, the risk of metal contamination that may be caused by deterioration of the surface of the substrate W can be prevented, even if the source gas S and the first and second process gases G1 and G2 are metal-corroding reaction gases.

In an embodiment, the first plasma openings O1, which penetrate the first plate PL1a, may be uniformly formed over the entire surface of the first plate PL1a. The number and the layout of first plasma openings OP1 of FIG. 5 may vary. Also, FIG. 5 illustrates that the first plasma openings O1 have a circular shape in a plan view. However, embodiments of the present disclosure are not necessarily limited thereto. Alternatively, the first plasma openings O1 may have a polygonal shape such as a rectangular shape, etc.

A right gas supply hole RH (FIG. 6) and a left gas supply hole LH (FIG. 6) may be formed at the bottom surface B1a of the first plate PL1a in the three-o'clock direction (e.g., the opposite direction of the second direction X) and the nine-o'clock direction (e.g., the second direction X), respectively. The right and left gas supply holes RH and LH may be connected to the second gas supply unit 400 of FIG. 1. In an embodiment, the first gas flow paths 110 may be divided into right gas flow paths 110R, which are connected to the right gas supply hole RH, and left gas flow paths 110L, which are connected to the left gas supply hole LH. The first gas openings GO1 may be divided into right gas openings GOR, which are connected to the right gas flow paths 110R, and left gas openings GOL, which are connected to the left gas flow paths 110L. In an embodiment shown in FIG. 6 the right gas flow paths 110R are connected to two right gas openings GOR and the left gas flow paths 110L are connected two left gas openings GOL. However, embodiments of the present disclosure are not necessarily limited thereto and the number of the first gas openings GO1 and the arrangement thereof may vary.

The first process gas G1 injected into the right gas flow paths 110R through the right gas supply hole RH may arrive at a right branch point RP. Then, the first process gas G1 may be vertically divided and may arrive at the right gas openings GOR, such as the upper and lower right gas openings GOR. In an embodiment, the distances from the right branch point RP to the right gas openings GOR may all be the same as a distance L1 (FIG. 7).

The first process gas G1 injected into the left gas flow paths 110L through the left gas supply hole LH may arrive at a left branch point LP. Then, the first process gas G1 may be vertically divided and may arrive at the left gas openings GOL, such as the upper and lower left gas openings GOL. In an embodiment, the distances from the left branch point LP to the left gas openings GOL may all be the same as a distance L2 (FIG. 7). In an embodiment, the distance L2 may be the same as the distance L1. In an embodiment, the right gas flow paths 110R and the left gas flow paths 110L may be formed symmetrically with one another. Accordingly, the first process gas G1 can be uniformly injected into the entire first zone Z1 of the showerhead 102a.

In an embodiment, a lower gas supply hole BH and an upper gas supply hole TH may be formed at the bottom surface B1a of the first plate PL1a in the six-o'clock direction (e.g., the opposite direction of a third direction Y) and the twelve-o'clock direction (e.g., the third direction Y), respectively. The lower and upper gas supply holes BH and TH may be connected to the third gas supply unit 500 of FIG. 1. The second gas flow paths 120 may be divided into lower gas flow paths 120B, which are connected to the lower gas supply hole BH, and upper gas flow paths 120T, which are connected to the upper gas supply hole TH. The second gas openings GO2 may be divided into first lower gas openings GO1B and second lower gas openings GO2B, which are connected to the lower gas flow paths 120B, and first upper gas openings GO1T and second upper gas openings GO2T, which are connected to the upper gas flow paths 120T. The first lower gas openings GO1B and the second lower gas openings GO2B may be spaced apart from each other in the second direction X.

The second process gas G2 injected into the lower gas flow paths 120B through the lower gas supply hole BH may arrive at a first lower branch point BP1. Then, the second process gas G2 may be horizontally divided and may arrive at second and third lower branch points BP2 and BP3 that are spaced apart from each other in the second direction X. In an embodiment, a distance L3 (FIG. 8) from the first lower branch point BP1 to the second lower branch point BP2 may be the same as a distance L4 (FIG. 8) from the first lower branch point BP1 to the third lower branch point BP3. In an embodiment, the distances from the second lower branch point BP2 to the first lower gas openings GO1B may all be the same as a distance L5 (FIG. 8). In an embodiment, the distances from the third lower branch point BP3 to the second lower gas openings GO2B may all be the same as a distance L6 (FIG. 8). The distance L6 may be the same as the distance L5.

The second process gas G2 injected into the upper gas flow paths 120T through the upper gas supply hole TH may arrive at a first upper branch point TP1. Then, the second process gas G2 may be horizontally divided (e.g., in the second direction X) and may arrive at second and third upper branch points TP2 and TP3. In an embodiment, a distance L7 (FIG. 8) from the first upper branch point TP1 to the second upper branch point TP2 may be the same as a distance L8 (FIG. 8) from the first upper branch point TP1 to the third upper branch point TP3 and may also be the same as the distance L3 (FIG. 8) from the lower branch point BP1 to the second lower branch point BP2 and the distance L4 (FIG. 8) from the first lower branch point BP1 to the third lower branch point BP3. In an embodiment, the distances from the second upper branch point TP2 to the first upper gas openings GO1T may all be the same as a distance L9 (FIG. 8), and the distance L9 may be the same as a distance L10 (FIG. 8) from the third upper branch point TP3 to the second upper gas openings GO2T, the distance L5 (FIG. 8) from the second lower branch point BP2 to the first lower gas opening GO1B, and the distance L6 (FIG. 8) from the third lower branch point BP3 to the second lower gas openings GO2B. The upper gas flow paths 120T and the lower gas flow paths 120B may be formed symmetrically with one another. Accordingly, the second process gas G2 can be uniformly injected into the entire second zone Z2 of the showerhead 102a.

As the showerhead 102a, which can filter out plasma having a particular electronic temperature or particular plasma ingredients, is formed by bonding three plates together, such as the first, second, and third plates PL1a, PL2a, and PL3a, and include the first gas flow paths 110 and the second gas flow paths 120, which can flow the first and second process gases G1 and G2 into the showerhead 102a, and the first and second cavities C1 and C2, into which the first and second process gases G1 and G2 can diffuse, the first and second process gases G1 and G2 can be uniformly sprayed over the surface of the substrate W. Also, since the showerhead 102a includes separate gas flow paths capable of flowing two or more process gases into the showerhead 102a, such as the first gas flow paths 110 and the second gas flow paths 120, and the first and second cavities C1 and C2 are provided, the distribution on the substrate W can be increased by controlling the reaction distribution in the center area of the substrate W and the reaction distribution in the edge area of the substrate W independently.

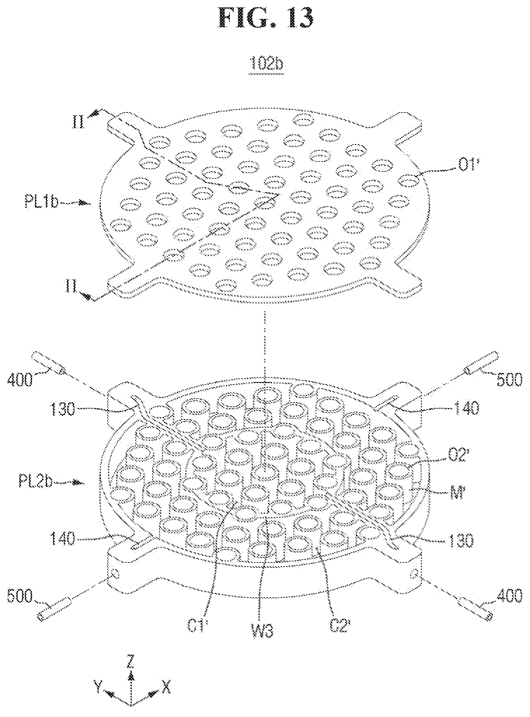

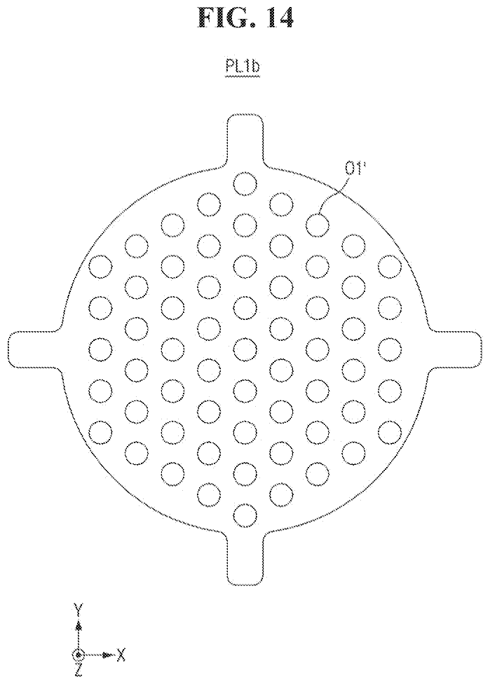

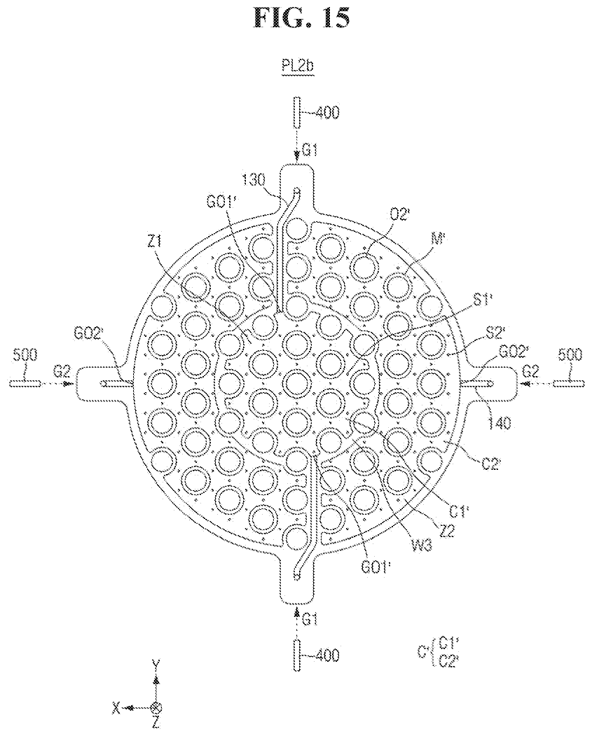

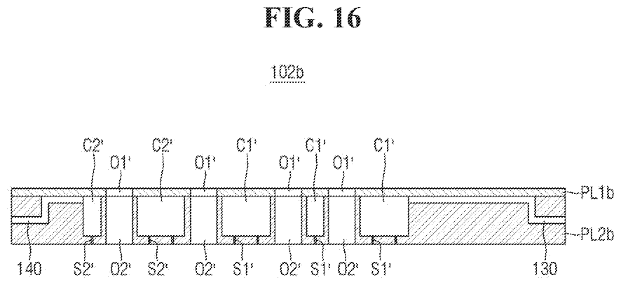

FIG. 13 is an exploded perspective view of a showerhead according to some embodiments of the present disclosure. FIG. 14 is a diagram of a first plate shown in FIG. 13. FIG. 15 is a diagram of a second plate of FIG. 13. FIG. 16 is a cross-sectional view, taken along line II-II, of the showerhead of FIG. 13.

A showerhead according to some embodiments of the present disclosure will hereinafter be described with reference to FIGS. 13 through 16.

In an embodiment, a showerhead 102b may be formed by bonding first and second plates PL1b and PL2b together. The showerhead 102b may be formed by bonding the first and second plates PL1b and PL2b such that the bottom surface of the first plate PL1b and the upper surface of the second plate PL2b may face each other. Here, the bottom surface of the first plate PL1b and the upper surface of the second plate PL2b may be defined with respect to the first direction Z.

The first plate PL1b may include first plasma openings O1′, which penetrate the first plate PL1b (e.g., in the first direction Z). The second plate PL2b may include second plasma openings O2′, which penetrate the second plate PL2b (e.g., in the first direction Z). When the first and second plates PL1b and PL2b are bonded together, the first plasm openings O1′ and the second plasma openings O2′ may overlap with each other (e.g., in the first direction Z), and be connected to one another. When the showerhead 102b is formed by bonding the first and second plates PL1b and PL2b, the first plasma openings O1′ and the second plasma openings O2′ may collectively form plasma penetration portions (“107” of FIG. 1).

First gas flow paths 130 and second gas flow paths 140 may be formed in the second plate PL2b. The first gas flow paths 130 may be connected to the gas supply unit 400, and as a result, the first process gas G1 may be injected into the showerhead 102b through the first gas flow paths 130. The second gas flow paths 140 may be connected to the third gas supply unit 500, and as a result, the second process gas G2 may be injected into the showerhead 102b through the second gas flow paths 140. In an embodiment, the first gas flow paths 130 may inject the first process gas G1 into a first zone Z1, which is the center area of the showerhead 102b, and the second gas flow paths 140 may inject the second process gas G2 into a second zone Z2, which is the edge area of the showerhead 102b. The first and second process gases G1 and G2 can be injected into the showerhead 102b through separate independent gas flow paths, such as the first gas flow paths 130 and the second gas flow paths 140. First gas openings GO1′ (FIG. 15) may be formed at the ends of the first gas flow paths 130 so that the first process gas G1 injected into the second plate PL2b through the first gas flow paths 110 may diffuse within the second plate PL2b. Similarly, the second process gas G2 injected into the second plate PL2b through the second gas flow paths 140 may diffuse within the second plate PL2b through second gas openings GO2′ (GO2), which are formed at the ends of the second gas flow paths 120.

In an embodiment, cylindrical members M′, which are connected to the second plasma openings O2′, may be formed at the bottom surface of the second plate PL2b. Due to the width of the cylindrical member M′ (e.g., in the first direction Z), cavities C′ may be formed in the second plate PL2b. In an embodiment, the cavities C′ may be divided into first and second cavities C1′ and C2′ by a partition W3, which is formed in the second plate PL2b. In an embodiment, the first cavity C1′, which corresponds to the first zone Z1 of the showerhead 102b, may be formed in the center area of the showerhead 102b. The second cavity C2′, which corresponds to the second zone Z2 of the showerhead 102b, may be formed in the edge area of the showerhead 102b.

The first process gas G1 diffused into the first cavity C1′ through the first gas openings GO1′ may be sprayed into the second plasma region P2 of FIG. 1 through first gas spraying holes S1′, which are formed at the bottom of the second plate PL2b to face the second plasma region P2. The second process gas G2 diffused into the second cavity C2′ through the second gas openings GO2′ may be sprayed into the second plasma region P2 through second gas spraying holes S2′, which are formed at the bottom surface of the second plate PL2b to face the second plasma region P2.

As the showerhead 102b, which can filter out plasma having a particular electronic temperature or particular plasma ingredients, is formed by bonding two plates together, such as the first and second plates PL1b and PL2b, and the showerhead 102b includes the first gas flow paths 130 and the second gas flow paths 140, which can flow the first and second process gases G1 and G2 into the showerhead 102b, and the first and second cavities C1′ and C2′, into which the first and second process gases G1 and G2 can diffuse, the first and second process gases G1 and G2 can be uniformly sprayed over the surface of the substrate W. Also, as the showerhead 102b includes separate gas flow paths capable of flowing two or more process gases into the showerhead 102b, such as the first gas flow paths 130 and the second gas flow paths 140, and the first and second cavities C1′ and C2′ are provided, the distribution on the substrate W can be increased by controlling the reaction distribution in the center area of the substrate W and the reaction distribution in the edge area of the substrate W independently.

Non-limiting embodiments of the present disclosure have been described above with reference to the accompanying drawings. However, embodiments of the present disclosure are not necessarily limited thereto and may be implemented in various different forms. It will be understood that embodiments of the present disclosure can be implemented in other specific forms without changing the technical spirit or gist of the present disclosure. Therefore, it should be understood that the embodiments set forth herein are illustrative and not necessarily limiting.

What is claimed is:

1. A semiconductor manufacturing device comprising:
a chamber including a space for performing processes therein;
a support unit in the chamber, the support unit supporting a substrate;
a first plasma region in the chamber, wherein plasma based on a source gas is generated in the first plasma region;
a second plasma region in the chamber and positioned below the first plasma region, the support unit is disposed in the second plasma region;
a showerhead disposed between the first plasma region and the second plasma region;
a first gas supply unit injecting a first process gas into the second plasma region through the showerhead; and
a second gas supply unit injecting a second process gas into the second plasma region through the showerhead,
wherein the showerhead includes:
plasma penetration portions passing a portion of the plasma generated in the first plasma region therethrough;
first gas flow paths injecting the first process gas into a first zone of the showerhead, the first gas flow paths are connected to the first gas supply unit;
second gas flow paths injecting the second process gas into a second zone of the showerhead that surrounds the first zone, the second gas flow paths are connected to the second gas supply unit;
a first cavity connected to the first gas flow paths, the first process gas diffuses into the first cavity;
a second cavity connected to the second gas flow paths, the second process gas diffuses into the second cavity;
first gas spraying holes connected to the first cavity and facing the second plasma region; and
second gas spraying holes connected to the second cavity and facing the second plasma region.

2. The semicondctor manufacturing device of claim 1, wherein:
the showerhead includes first and second plates bonded together,
the first plate includes first plasma openings penetrating the first plate,
the second plate includes second plasma openings penetrating the second plate, the second plasma openings are connected to the first plasma openings, the second plate further includes the first gas flow paths, the second gas flow paths, the first cavity, the second cavity, the first gas spraying holes, and the second gas spraying holes; and
the plasma penetration portions include the first plasma openings and the second plasma openings.

3. The semicondctor manufacturing device of claim 2, wherein the first and second plates include quartz.

4. The semicondctor manufacturing device of claim 1, wherein:
the showerhead includes first, second, and third plates bonded together;
the first plate includes first plasma openings penetrating the first plate;
the second plate includes second plasma openings penetrating the second plate, the second plasma openings are connected to the first plasma openings;
the third plate includes third plasma openings penetrating the third plate, the third plasma openings are connected to the first plasma openings and the second plasma openings; and
the plasma penetration portions include the first plasma openings, the second plasma openings, and the third plasma openings.

5. The semicondctor manufacturing device of claim 4, wherein the first plate includes the first gas flow paths and the second gas flow paths.

6. The semicondctor manufacturing device of claim 5, wherein the first gas flow paths and the second gas flow paths are disposed at a bottom surface of the first plate.

7. The semicondctor manufacturing device of claim 5, wherein the second plate includes the first cavity and the second cavity.

8. The semicondctor manufacturing device of claim 7, wherein the second plate includes first holes passing the first process gas therethrough, and second holes passing the second process gas therethrough.

9. The semicondctor manufacturing device of claim 8, wherein:
the first process gas diffuses into the first cavity through the first holes; and
the second process gas diffuses into the second cavity through the second holes.

10. The semicondctor manufacturing device of claim 9, wherein:
the third plate includes the first gas spraying holes and the second gas spraying holes;
the first process gas in the first cavity is sprayed into the second plasma region through the first gas spraying holes; and
the second process gas in the second cavity is sprayed into the second plasma region through the second gas spraying holes.

11. The semicondctor manufacturing device of claim 10, wherein:
a number of the first gas spraying holes is greater than a number of the first holes; and
a number of the second gas spraying holes is greater than a number of the second holes.

12. The semicondctor manufacturing device of claim 1, wherein:
the portion of the plasma generated in the first plasma region that is passed through the plasma penetration portions has an electronic temperature less than or equal to a preset electronic temperature; and
the portion of the plasma generated in the first plasma region that is passed through the plasma penetration portions is transmitted to the second plasma region.

13. The semicondctor manufacturing device of claim 1, wherein plasma included in the first plasma region has a higher electronic temperature than plasma included in the second plasma region.

14. The semicondctor manufacturing device of claim 1, further comprising:
a third gas supply unit injecting the source gas into the first plasma region.

15. The semicondctor manufacturing device of claim 1, wherein the support unit rotates the substrate.

16. The semicondctor manufacturing device of claim 1, wherein the support unit includes a heater controlling a temperature of the substrate.

17. A semicondctor manufacturing device comprising:
a first plate including first plasma openings penetrating the first plate, first gas flow paths injecting a first process gas into a first zone, and second gas flow paths inject a second process gas into a second zone that surrounds the first zone;
a second plate including second plasma openings penetrating the second plate and are connected to the first plasma openings, first holes passing the first process gas therethrough, second holes passing the second process gas therethrough, a first cavity diffusing the first process gas injected through the first holes, and a second cavity diffusing the second process gas injected through the second holes; and
a third plate including third plasma openings connected to the first plasma openings and the second plasma openings, first gas spraying holes passing the first process gas from the first cavity therethrough and spraying the first process gas to an outside of the showerhead, and second gas spraying holes passing the second process gas from the second cavity therethrough and spraying the second process gas to the outside of the showerhead,
wherein:
the first and second plates are bonded together, wherein a bottom surface of the first plate and an upper surface of the second plate face each other; and
the second and third plates are bonded together, wherein a bottom surface of the second plate and an upper surface of the third plate face each other.

18. The semicondctor manufacturing device of claim 17, wherein the first, second, and third plates include quartz.

19. The semicondctor manufacturing device of claim 17, wherein a number of the first gas spraying holes is greater than a number of the first holes.

20. A semicondctor manufacturing device comprising:
a first plate including first plasma openings penetrating the first plate; and
a second plate including second plasma openings penetrating the second plate, the second plasma openings are connected to the first plasma openings, the second plate further includes first gas flow paths injecting a first process gas into a first zone, second gas flow paths injecting a second process gas into a second zone that surrounds the first zone, a first cavity disposed in the first zone, wherein the first process gas is injected into the first cavity through the first gas flow paths, a second cavity disposed in the second zone, wherein the second process gas is injected into the second cavity through the second gas flow paths, first gas spraying holes spraying the first process gas from the first cavity to an outside of the showerhead, and second gas spraying holes spraying the second process gas from the second cavity to the outside of the showerhead,
wherein the showerhead includes the first and second plates bonded together, wherein a bottom surface of the first plate and an upper surface of the second plate face each other.
